(19) United States
(12) Patent Application Publication
(10) Pub. No.: US 2015/0241487 A1
(43) Pub. Date: Aug. 27, 2015

(54) ESTIMATION OF ELECTRIC ENERGY CONSUMPTION OF A GIVEN DEVICE AMONG A SET OF ELECTRICAL DEVICES

(71) Applicant: ELECTRICITE DE FRANCE, Paris (FR)

(72) Inventors: Laurent Bozzi, Le Plessis-Trevise (FR); Gregory Yard, Bagneux (FR)

(21) Appl. No.: 14/632,292

(22) Filed: Feb. 26, 2015

(30) Foreign Application Priority Data
Feb. 26, 2014 (FR) 14 51531

(51) Int. Cl. G01R 21/133

(52) U.S. Cl. CPC G01R 21/133

(57) ABSTRACT

A method for estimating the electric energy consumption of a given electrical device among a set of electrical devices, comprising the steps of: receiving a load curve representative of the electric energy consumption of said set of electrical devices at given moments, over a given period; determining a lower envelope of said load curve; estimating an electric energy consumption curve for the given electrical device over the given period, by subtracting the determined lower envelope from said load curve.

### CROSS-REFERENCE TO RELATED PATENT APPLICATION

This application claims the benefit of French Patent Application No. 14 51531, filed on Feb. 26, 2014, in the French Institute of Industrial Property, the entire content of which is incorporated herein by reference.

### BACKGROUND

The invention relates to estimating the electric energy consumption of a device among a set of devices, particularly but not exclusively to estimating the consumption of a water heater with storage tank (hereinafter referred to as a “hot water tank”) in a home, based on a load curve corresponding to the total electric energy consumption of the household.

It has applications in optimizing the total load curve by shifting the activation periods of the hot water tank, as well as in providing the customer with detailed electricity consumption measurements.

In a context of developing intelligent electricity distribution networks (“SmartGrids”) to optimize production, distribution, and consumption, and of an increasing use of renewable energy, the general production of electricity is tending to become decentralized which places heavy constraints on maintaining a balance between electricity supply and demand.

With renewable energy, solar (photovoltaic) energy is a special case because it is almost certain to occur during midday hours. However, this surplus energy does not correspond to the hours of peak electric energy consumption which are generally between 7 and 9 am in the morning, and 6 and 8 pm in the evening. There is therefore a need to “absorb” such energy.

In residential consumption, one of the usages with the most flexibility is the heating of domestic hot water (DHW) in hot water tanks. Such tanks, which are found in most homes, can be considered to “store” electricity because their consumption of the electricity required to heat a volume of water occurs before the hot water is withdrawn for household needs.

It is thus possible to shift DHW electric energy consumption, which generally takes place in off-peak hours during the night, to off-peak midday hours, in order to “absorb” the surplus solar energy produced during these off-peak midday hours. “Off-peak hours” is a period during which the total electric energy consumption is relatively low for a large group of households, and during which the cost associated with electric energy consumption is reduced. Such periods are not fixed (they depend on the season in particular) and depend on the energy production and distribution companies.

In order to optimize shifting of the activation periods of hot water tanks, the DHW electric energy consumption for the next day can be predicted, in particular using predictive models based on a history of DHW electric energy consumption during the preceding days.

It is then necessary to know DHW electric energy consumption for every household. Such knowledge also allows providing the customer with a detailed bill (itemized by usage).

There are existing solutions for differentiating a total load curve of electricity consumption according to usage.

For example, the “Beluso” algorithm proposed by the Fludia company proposes breaking down an individual total load curve (for a household) by usage. To do this, it requires knowledge of the total load curve over a given period, but also requires additional information on the residence itself. For example, a questionnaire needs to be completed by the household to provide information concerning the square footage of the residence as well as the major appliances.

Another solution was proposed in the thesis of Mabrouka EL GUEDRI defended on Nov. 9, 2009, entitled “Caractérisation aveugle de la courbe de charge électrique: Détection, classification et estimation des usages dans les secteurs résidentiel et tertiaire”. The method used in this thesis consists of extracting the DHW electric energy consumption curve from a total load curve where the total load curve is based on consumption readings obtained every second, which is an expensive approach to implement.

Other known solutions are based on NILM or NIALM technology (“Non Intrusive Appliance Load Monitoring”), which consists of a process of analyzing load and voltage variations in a residence in order to deduce the appliances in use and their respective consumptions. However, such a process again requires obtaining readings at a high frequency ranging from the Hertz to the kiloHertz (kHz). As mentioned above, such frequencies involve high costs.

There is therefore a need to estimate the electric energy consumption of a device among a set of electrical devices without prior knowledge of the devices and without requiring a high frequency in obtaining readings of the total load of the devices.

The present invention improves the situation.

### SUMMARY

A first aspect of the invention relates to a method for estimating the electric energy consumption of a given electrical device among a set of electrical devices, comprising the steps of:
receiving a load curve representative of the electric energy consumption of the set of electrical devices at given moments, over a given period;
determining a lower envelope of the load curve;
estimating an electric energy consumption curve for the given electrical device over the given period, by subtracting the determined lower envelope from the load curve.

Taking into account the lower envelope of the load curve allows using a load curve having a measurement interval of a minute or more, reducing the cost associated with obtaining the load curve compared to techniques of the prior art. In addition, the method of the invention does not require knowing all the devices, and the customer then does not need to fill out a declarative form beforehand. The estimation of the electric energy consumption curve of the electrical device can enable different applications:
providing a detailed invoice to the customer, by usage;
predicting a length of operation of the device for future periods, particularly in order to optimize energy production or to move the periods of operation of the device in order to synchronize the supply and demand for electrical energy.

According to one embodiment of the invention, the given moments can be spaced apart at regular intervals, the regular intervals being greater than one minute.

For example, a 30 minute interval can be planned, which greatly reduces the costs associated with obtaining the load curve.

In one embodiment, the given electrical device can be a hot water tank and the given period can include at least one period of off-peak hours, and the estimation of the electric energy consumption curve of the electrical device can be restricted to the period of off-peak hours.

Therefore the invention advantageously finds application in the field of domestic hot water, where energy can be stored. The heating of hot water tanks is a usage where the operation can be assigned relatively flexibly to a given time slot. By predicting the length of operation of the hot water tank, it is possible to move the operation of hot water tanks to time slots where excess energy is being produced.

According to one embodiment of the invention, the method may further comprise a step of estimating the maximum power consumed by the given device, and a step of applying a first correction to the estimated curve in order to obtain a first corrected curve, the first correction consisting of limiting the power consumed by the electrical device to values less than the maximum power, over the given period.

Such an embodiment improves the accuracy associated with the estimate of the electric power consumed by the given device.

According to one embodiment, the volume of the hot water tank can be known and the maximum power consumed can be estimated from the volume of the hot water tank.

The maximum power can thus be deduced in a simple manner.

Alternatively, a continuous load curve representing the electric energy consumption of the set of devices for a period prior to the given period is stored, the prior period being continuous and comprising at least some periods of off-peak hours and periods of peak hours, and the step of estimating the maximum power consumed by the electrical device may comprise:
determining, for each prior period of off-peak hours, the difference between the value of the load curve at moment one or at moment two of the period of off-peak hours and the value of the load curve at the moment immediately preceding moment one;
estimating, from the determined differences, the maximum power consumed by the electrical device.

In this variant, the maximum power can be obtained without prior knowledge of the given device.

According to one embodiment of the invention, upon receipt of the load curve, the method may comprise the application of a wavelet decomposition in order to obtain a denoised load curve, and the lower envelope can be determined from the denoised load curve, and the electric energy consumption curve of the given device can be estimated by subtracting the lower envelope from the denoised load curve over the given period.

This embodiment eliminates usages which consume little electric power when estimating the electric power consumed by the given electrical device.

According to one embodiment of the invention, the load curve may also be received for periods before and after the given period, and the step of determining the lower envelope of the load curve may comprise the following steps, for each moment in the given period:
determining the minimum value among the respective values of the load curve for the n moments before the given moment, for the given moment, and for the n moments after the given moment, where n is an integer greater than or equal to one;
assigning the determined minimum value to that moment.
   The minimum values can then be connected to obtain the lower envelope of the load curve.

Additionally, the rate of change T[P(t)] of the load curve at a given moment t of the given period is determined as follows:

T[P(t)]=[P(t)−P(t−1)/P(t−1);

where P(t) represents the power consumed by the set of devices at given moment t and where P(t−1) represents the power consumed by the set of devices at moment t−1 directly preceding given moment t.
The method may further comprise a step of applying a second correction to the estimated curve denoted ECS₁, in order to obtain a second corrected curve denoted ECS₂, where t₀ is the starting moment of a period of off-peak hours of the given period, a variable ECS_plateau being initialized to the value of the estimated curve ECS₁ at moment t₀, the second corrected curve being obtained in the following manner for all moments t after moment t₀ of said period of off-peak hours:

```
if t < t₀ + th₁ and if |T[P(t)] < th₂, then ECS₂(t) = Max(ECS_plateau*
(1 + T[P(t)]; ECS₁(t))
else
  if t ≧ t₀ + th₁ and T[P(t)] < th₃, then ECS₂(t) = ECS₁(t) and
  ECS_plateau = ECS₁(t);
  else
    if T[P(t)] < −th₄ or T[P(t)] > th₂ then ECS₂(t) = ECS₁(t) and
    ECS_plateau is set to the value of ECS₁(t) for the moments
    subsequent to moment t in the period of off-peak hours;
    else ECS₂(t )= ECS₁(t);
```

where Max(A,B) indicates the maximum value among A and B;
where th₁ is a predetermined threshold expressed in hours;
where th₂, th₃, and th₄ are predetermined thresholds expressed in percentages, th₃ being less than th₂.

Applying the second correction significantly improves the estimate of the power consumed by the given device.

In addition, denoting the maximum power consumed by the given device as Pmax, the method may further comprise a step of applying a third correction to the second corrected curve ECS₂ in order to obtain a third corrected curve, denoted ECS₃, and the third corrected curve may be obtained in the following manner for all moments t preceding moment t₀+th₁:

$$if {ECS}_{2} ( t ) < \frac{P max}{3} , if {ECS}_{2} ( t - 1 ) > \frac{2 * P max}{3} , and if {ECS}_{2} ( t + 1 ) > \frac{2 * P max}{3}$$

$$then {ECS}_{3} ( t ) = \frac{{ECS}_{2} ( t - 1 ) + {ECS}_{2} ( t + 1 )}{2} ;$$

$$else {ECS}_{3} ( t ) = {ECS}_{2} ( t ) .$$

In addition, the third correction improves the accuracy of the method and approaches the true consumption curve for the given device.

Additionally or alternatively, the given device may operate in activation periods contained within a period of off-peak hours of the given period, electric power being consumed by the given electrical device only during the activation periods, the period of off-peak hours comprising at least a first activation period and a second activation period.

The method may further comprise the application of a fourth correction to the second corrected curve ECS₂ in order to obtain a fourth corrected curve denoted ECS₄, the fourth correction comprising:
determining a moment t₁ of demarcation between the first activation period and the second activation period;
determining a second activation threshold th_{second}, expressed in percentages; and the fourth corrected curve ECS₄ can be obtained as follows:

$$for t ∈ [ {t}_{0} ; {t}_{1} ] , {ECS}_{4} ( t ) = {ECS}_{2} ( t ) ; \\ for t ∈ ] {t}_{1} ; {t}_{f} ] , {ECS}_{4} ( t ) = Min \{ {Max}_{t < {t}_{1}} \{ {ECS}_{2} ( t ) \} \times {th}_{second} ; {ECS}_{2} ( t ) \}$$

Min(A;B) indicating the minimum among A and B;
t_{f} being an ending moment of the given period.

Alternatively, the fourth correction can be applied to the third corrected curve ECS₃.

The fourth correction also improves the accuracy of the estimate of the electric power consumed by the given device, by limiting the estimates of power draws by the electrical device in the second activation periods.

According to one embodiment of the invention, the method may further comprise predicting the length of operation of the given electrical device for a period subsequent to the given period, based on the electric energy consumption curve of the electrical device over the given period.

A second aspect of the invention relates to a computer program product comprising program instruction code stored on a computer-readable medium, for executing the steps of the method according to the first aspect of the invention.

A third aspect of the invention relates to a device for estimating the electric energy consumption of a given electrical device among a set of electrical devices, comprising:
a unit for receiving a load curve representative of the electric energy consumption of the set of electrical devices at given moments, over a given period;
a unit for determining a lower envelope of the load curve;
a unit for estimating an electric energy consumption curve of the electrical device for the given period, by subtracting the determined lower envelope from the load curve.

### BRIEF DESCRIPTION OF THE DRAWINGS

Other features and advantages of the invention will become apparent upon examining the following detailed description and the accompanying drawings in which:

FIG. 1 shows a system according to an embodiment of the invention;

FIG. 2 is a diagram illustrating the evolution of the total electric energy consumption of a set of electrical devices, over a period prior to a given period;

FIG. 3 is a monotonic curve of N values of the maximum power drawn by a given device;

FIG. 4 is a diagram illustrating a total load curve of a set of electrical devices over a given period;

FIG. 5 is a diagram illustrating a total load curve of a set of electrical devices and the lower envelope of the limited load curve, over a given period;

FIG. 6 is a diagram illustrating a total load curve of a set of electrical devices and the lower envelope of the load curve limited to periods of off-peak hours, over a given period;

FIG. 7 is a diagram illustrating a total load curve of a set of electrical devices, the lower envelope of the load curve, and an estimated electric energy consumption curve for a given device among the set of electrical devices, over a given period;

FIG. 8 is a diagram illustrating an actual consumption curve of a given electrical device and an estimated consumption curve of the electrical device, over a given period;

FIG. 9 is a diagram illustrating an actual consumption curve of a given electrical device, an estimated consumption curve of the electrical device, and a first corrected consumption curve of the electrical device, over a given period;

FIG. 10 is a diagram illustrating a consumption curve of a given electrical device, an estimated consumption curve of the electrical device, and a second corrected consumption curve of the electrical device, over a given period;

FIG. 11 is a diagram illustrating two consumption curves of a given device, derived from recorded measurements obtained at two different regular intervals, over a given period;

FIG. 12 is a diagram illustrating an actual consumption curve of a given electrical device, an estimated consumption curve of the electrical device, and a fourth corrected consumption curve of the electrical device, over a given period;

FIG. 13 is a diagram representing the steps of the method according to an embodiment of the invention.

### DETAILED DESCRIPTION

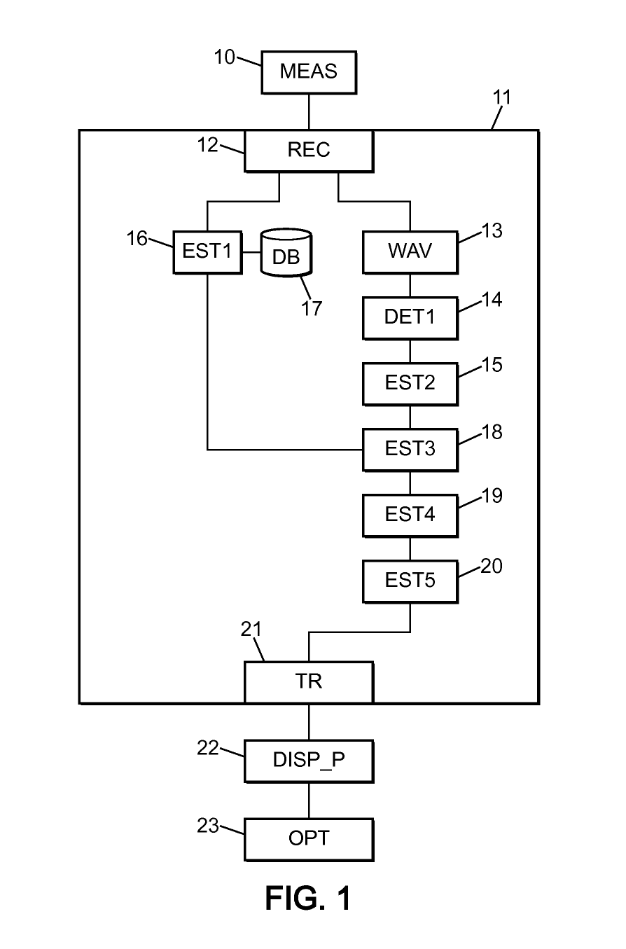

FIG. 1 illustrates a system according to an embodiment of the invention.

The system comprises a measurement unit which measures the electric energy consumption of a set of electrical devices. For example, the set of devices can correspond to the electrical appliances of a residence, and includes a given electrical device whose electric energy consumption is estimated by the system according to the invention. The given electrical device may be, for example, a residential hot water tank. Such a hot water tank operates intermittently in “all or nothing” mode. “Activation periods” are those periods during which the hot water tank consumes electric power. Generally, at the start of off-peak hours, the maximum power is drawn by the hot water tank for a given length of time until the water contained in the tank reaches a set temperature. It can then be reheated during the off-peak hours, if the temperature of the water in the tank drops.

The measurements can be obtained at given moments, for example at regular time intervals. These intervals are called “regular intervals” in the following description. According to the invention, the regular interval used is at least a minute, which advantageously reduces the costs associated with measuring electric energy consumption, compared to techniques of the prior art which require an interval of a second or less.

In the following description, a regular interval of 30 minutes is preferably used. However, no restriction is placed on the interval, and the example of the 30 minute interval is used for illustrative purposes.

Such a measurement device may, for example, be implemented in a household electrical box.

From successive readings during a given period, the measurement unit 10 can create a load curve representative of the electric energy consumption of the set of electrical devices. The load curve thus created can be sent to an estimation device 11 according to one embodiment of the invention. Alternatively, the measurement unit 10 may simply send periodically to the estimation device 11 an isolated measurement of the total power consumed, and the load curve is then created by the estimation device 11.

The given period may, for example, correspond to a day or to several days. It may be restricted to periods of off-peak hours only. No restrictions are placed on the given period considered.

The estimation device 11 comprises a receiving unit 12 for receiving the load curve (or alternatively the raw measurements from the measurement unit 10, in which case the receiving unit may also create the load curve).

A first estimation unit 16 of the estimation device 11 is able to estimate the maximum power (denoted Pmax) that may be consumed (or “drawn”) by the hot water tank.

According to one embodiment, the value of Pmax can be estimated from the volume of the hot water tank.

The relationship between the volume and the maximum power of the tank is generally known. For example, the following equivalences can be considered:
a 100 L tank is equivalent to a power Pmax of 1200 Watts (W);
a 150 L tank is equivalent to a power Pmax of 1800 W;
a 200 L tank is equivalent to a power Pmax of 2200 W;
a 300 L tank is equivalent to a power Pmax of 3000 W.

For other hot water tank volumes, the following values can be used:
12 times the volume of the tank in liters to obtain the power in watts for volumes less than 175 L;
11 times the volume of the tank in liters to obtain the power in watts for volumes between 175 L and 250 L;
10 times the volume of the tank in liters to obtain the power in watts for volumes between 250 L and 350 L;
8 times the volume of the tank in liters to obtain the power in watts for volumes greater than 350 L.

Such an embodiment, however, requires prior knowledge of the volume of the hot water tank.

To overcome this disadvantage, the invention provides another embodiment for determining the power Pmax.

According to this second embodiment, a total load curve providing measurements during the period prior to the given period are stored in a database 17 of the estimation device 11. The prior period is preferably continuous and thus includes both periods of off-peak hours and periods of peak hours.

This second embodiment is based on the fact that, during off-peak hours, the hot water tank is in operation and runs at full power. If no other usage (no other household appliances are in operation) impacts the load, the Pmax value is the difference between the load value at moment one (or the first regular interval) of the period of off-peak hours, or the load value at moment two (or the second regular interval) of the period of off-peak hours, and the value of the load just prior to the off-peak activation (during a period of peak hours).

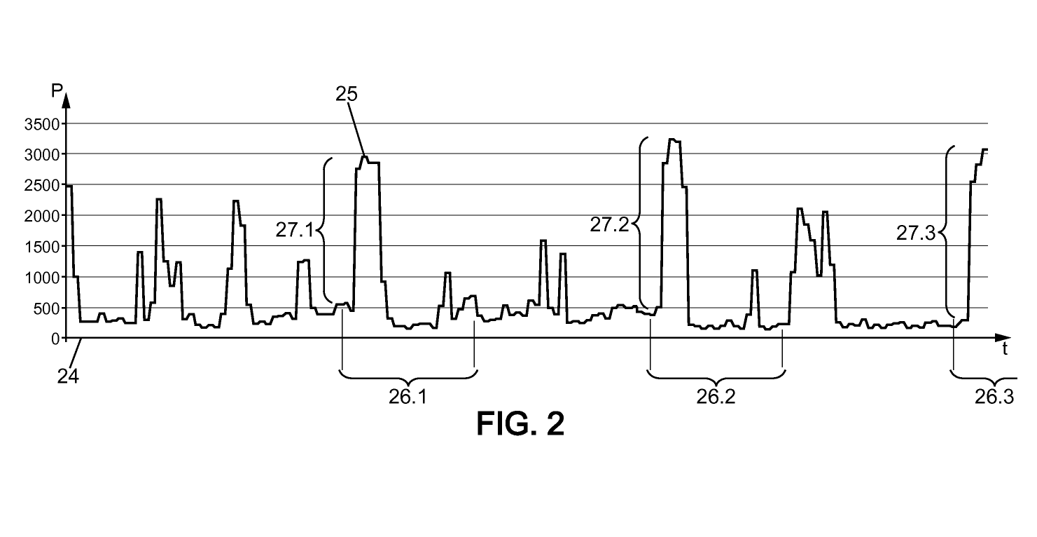

FIG. 2 is a diagram 24 showing the total load curve 25, comprising three periods of off-peak hours labeled 26.1, 26.2, and 26.3. The total load curve 25 thus shows the evolution in the total electric energy consumption of the set of electrical devices of the household, over a period prior to the given period, measured at regular intervals of thirty minutes.

As shown in diagram 24, the total load curve 25 reaches maximum values at the start of the periods of off-peak hours 26.1, 26.2, and 26.3, either during the first thirty minutes of each period of off-peak hours or during the next thirty minutes.

The respective differences between these maximum values and the values directly preceding activation in the periods of off-peak hours are labeled 27.1, 27.2, and 27.3. It is possible to obtain the power Pmax by averaging these differences.

A problem arises, however, when usages other than heating the hot water tank are drawing power during activation in the periods of off-peak hours (for example the washing machine, dishwasher).

Here, the invention proposes using a curve called a monotonic curve, representing N difference values 27.1, 27.2, 27.3, for a set of N periods of off-peak hours prior to the given period. In order to obtain reliable results, a number N greater than 100 may be provided. The monotonic curve shows the values of the differences 27.1, 27.2, 27.3 in descending order, versus an index of each period of the N previous periods of off-peak hours.

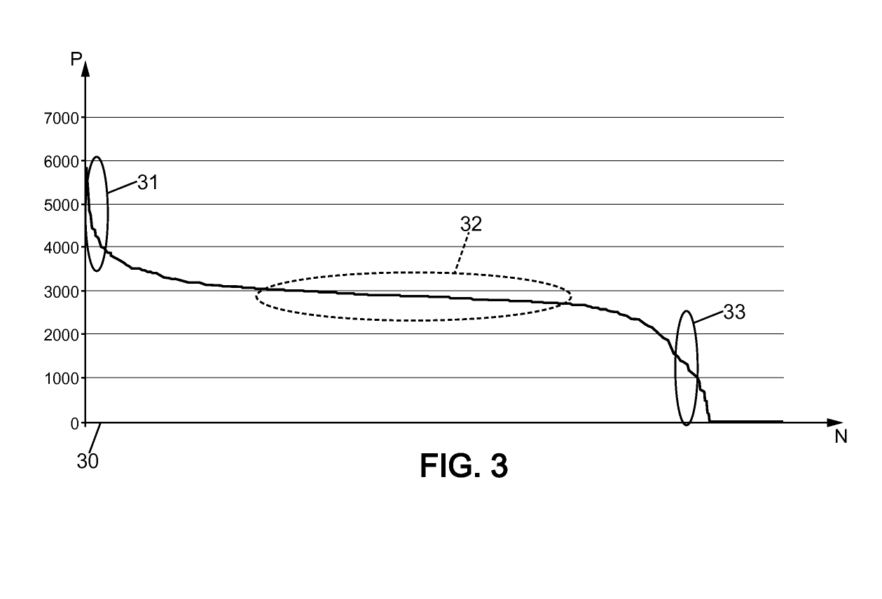

Such a monotonic curve is shown in diagram 30 of FIG. 3.

The values of the differences are greatest in region 31. They are obtained during periods of off-peak hours where activation of the tank is accompanied by activation of some other usage.

The values of the differences are minimal in region 33. They are obtained for periods of off-peak hours with little or no use of the hot water tank.

However, in region 32, the values of the differences correspond to periods of off-peak hours where only the hot water tank was drawing the maximum power.

An algorithm allows detection of such a plateau (region 32) in the monotonic curve. The algorithm can scan the N consecutive points and stop when the ratio P(k)/P(k−2) is close to 1 (for example, greater than 0.998) for M consecutive points, with P(k) being the value of the difference obtained for the k-th period of off-peak hours among the N periods of off-peak hours, M being greater than N. As an example, N can be set to 9.

Such an embodiment does not require knowing the volume of the water tank. However, it requires storing the load curve for a long prior period, for example a period several months long.

The use of the Pmax value will be detailed below.

The estimation device 11 further comprises a denoising unit 13, whose use is optional in the context of the invention.

The denoising unit 13 uses wavelet decomposition to reduce noise in the load curve received by the receiving unit 12. Wavelet decomposition is a compression method commonly used in signal processing (for example in image compression with the algorithm for the “jpeg” standard or in audio with the “mp3” compression algorithm). It consists of decomposing a signal by superimposing simple functions.

A description of wavelet transforms is presented in the “Gwyddion User Guide” by Petr Klapetek, David Necas, and Christopher Andreson, French translation by Francois Riguet, Jan. 14, 2014 version, chapter 4, “Wavelet transform” section.

Applying wavelet decomposition to a signal uses thresholding to erase the small amplitudes of the signal while preserving the large amplitudes.

In the present case, only the thresholding function can be used. Subroutines in the SAS/IML language can be used for this. They implement a fast wavelet transform, called WAVFT) that calculates a discrete wavelet transform using Mallet's algorithm.

The decomposition can be configured to select the third member of Daubechies wavelets, the form of their basis functions being well known to the skilled person.

Once the decomposition is performed, the first level is kept and the signal is reconstructed (WAVIFT function, for inverse fast wavelet transform) after thresholding to smooth out the insignificant coefficients. “SureShrink” soft thresholding can be used, from the document “Adapting to Unknown Smoothness via Wavelet Shrinkage” by L. Donoho and M. Johnstone, Journal of the American Statistical Association, Vol. 90, No. 432, December 1995, pages 1200 to 1224.

The load curve received by the receiving unit 12, and optionally denoised by the denoising unit 13, is sent to a first determination unit 14 for determining a lower envelope of the load curve.

To do so, the determination unit 14 may construct a lower envelope to the load curve by connecting the sliding minima on 2n+1 centered half-hourly intervals, n being greater than or equal to 1. For example, n may be 3.

Thus, for every moment of the given period, the minimum value is determined among the respective values of the load curve for n moments preceding the given moment, for the given moment, and for n moments after the given moment. This requires knowing the value for n moments preceding the given period and n moments following the given period. Each given moment is then assigned the determined minimum value. The minimum values are then connected to obtain the lower envelope of the load curve.

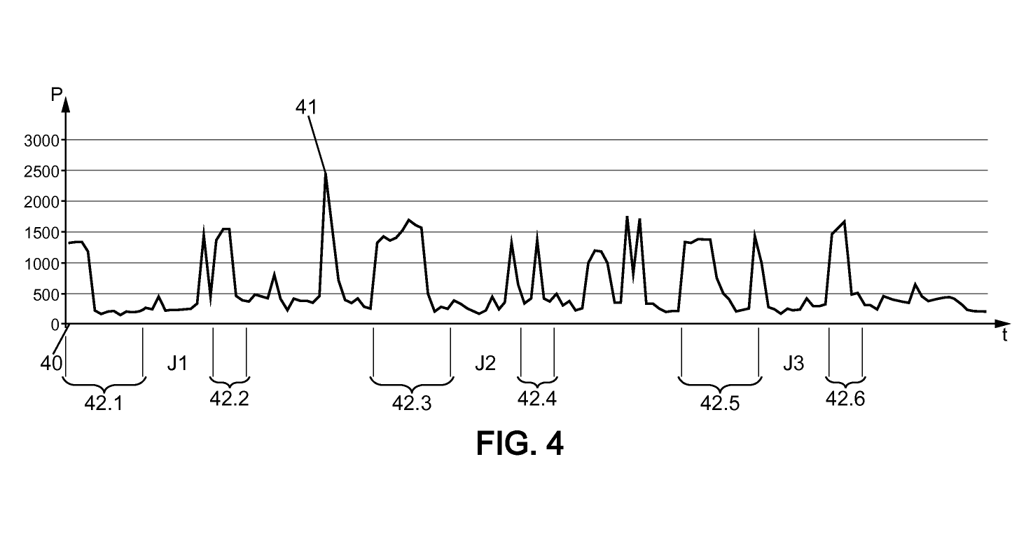

FIGS. 4 to 6 illustrate the operation of the determination unit 14.

FIG. 4 is a diagram 40 showing load curve 41 over a given period of three days, as received by the determination unit 14, the given period comprising six periods of off-peak hours labeled 42.1, 42.2, 42.3, 42.4, 42.5, and 42.6.

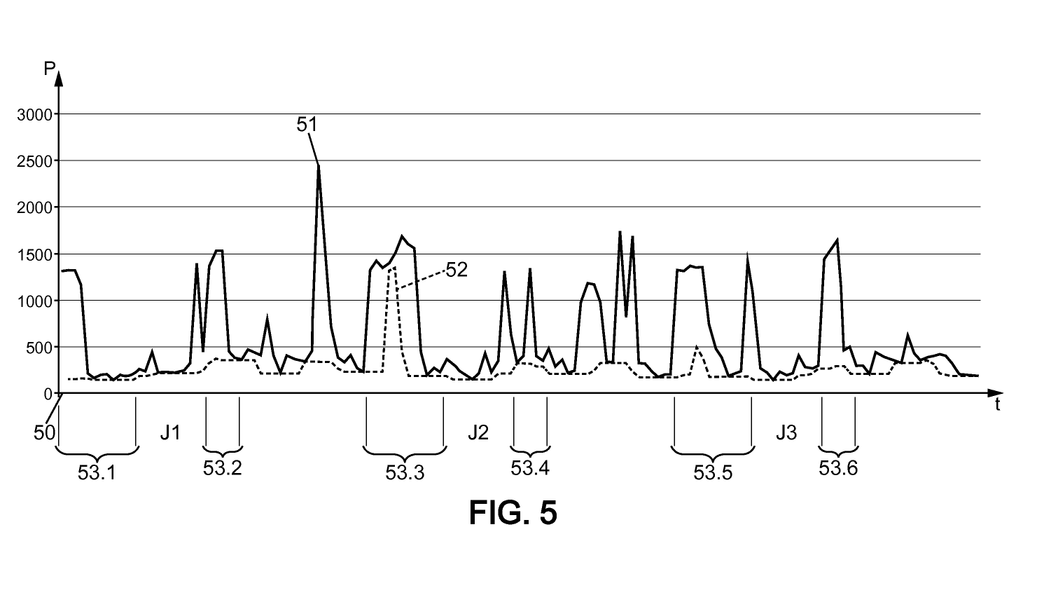

FIG. 5 is a diagram 50 showing load curve 51 (identical to load curve 41) over the same given period of three days, comprising the six periods of off-peak hours which are labeled 53.1, 53.2, 53.3, 53.4, 53.5, and 53.6. Diagram 50 further includes the lower envelope 52 of load curve 51, determined as described above, with a regular interval of 30 minutes and n equal to 3 (therefore with 7 sliding minima).

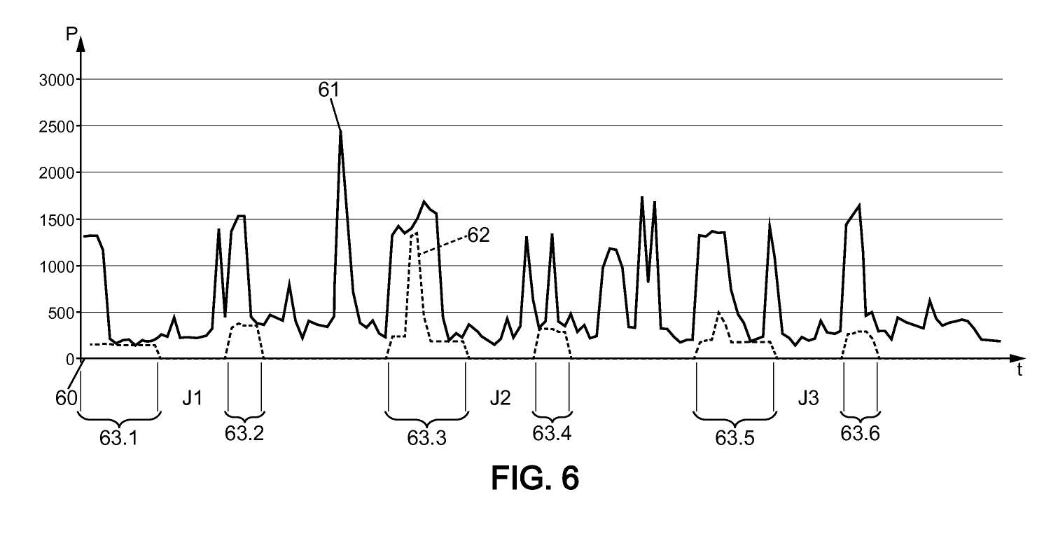

FIG. 6 is a diagram 60 showing load curve 61 (identical to load curves 51 and 41) over the same given period of three days, comprising the six periods of off-peak hours which are labeled 63.1, 63.2, 63.3, 63.4, 63.5, and 63.6. Diagram 60 further includes the lower envelope 62 of load curve 61, determined as described above, with a regular interval of 30 minutes and n equal to 3 (therefore with 7 sliding minima), and which has been restricted to the six periods of off-peak hours comparably to the lower envelope 52 of FIG. 5. Such a restriction to the periods of off-peak hours is optional in the invention. However, in the rest of the description and for illustrative purposes, the curves are restricted to off-peak hours.

The estimation device further comprises a second estimation unit 15 adapted to estimate an electric energy consumption curve of the hot water tank over the given period, by subtracting from the load curve the lower envelope determined by the determination unit 14.

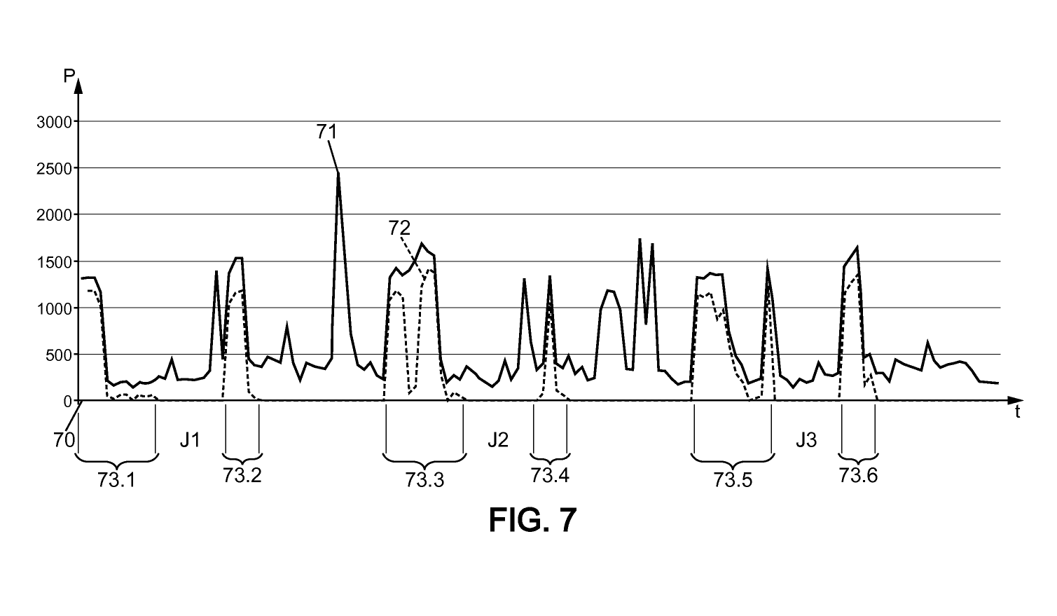

The resulting curve is shown in FIG. 7.

FIG. 7 is a diagram 70 showing load curve 71 (identical to load curves 41, 51, and 61) over the same given period of three days, comprising the six periods of off-peak hours which are labeled 73.1, 73.2, 73.3, 73.4, 73.5, and 73.6. Diagram 70 also shows the electric energy consumption curve 72 of the hot water tank, as estimated by the second estimation unit 15.

The device 11 thus provides the electric energy consumption curve of the hot water tank from a total load curve, without prior knowledge of the other household appliances and with the regular interval being longer than a minute. The use of the lower envelope of the load curve in the estimation method makes it possible to use an interval longer than a minute.

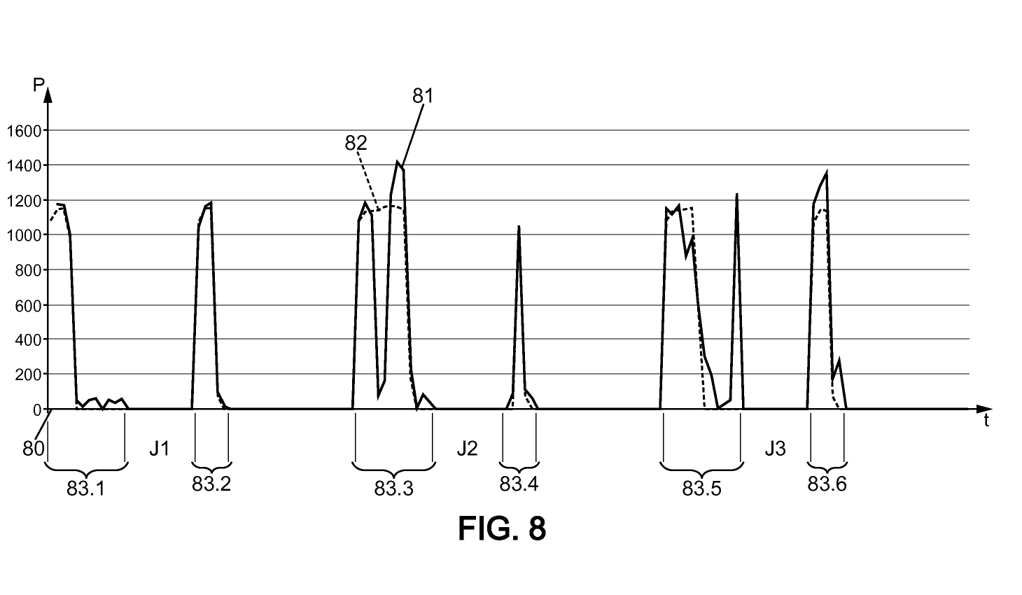

FIG. 8 is a diagram 80 showing the estimation 81 of the electric energy consumption curve of the hot water tank over the same given period of three days, including six periods of off-peak hours which are labeled 83.1, 83.2, 83.3, 83.4, 83.5, and 83.6. The estimation 81 is compared to the actual consumption 82 of the hot water tank over the given period.

The rest of the description below presents supplemental units that can make corrections to the estimation 81 and thus improve the accuracy associated with the estimation of the electric energy consumption of the hot water tank. In particular, the estimation 81 obtained by the estimation device 11 is less reliable during periods requiring heating (for example by electric heaters), as this consumption is included in the estimated electric energy consumption of the hot water tank. In addition, the estimation 81 overestimates the power draw during a second activation of the hot water tank during a same period of off-peak hours.

All corrective steps are optional.

A first corrective step can be implemented by a third estimation unit 18 of the estimation device 11. The third estimation unit 18 receives the power value Pmax from the first estimation unit 16. The first correction applied by the third estimation unit 18 consists of limiting the power consumed by the hot water tank to values below the maximum power value Pmax, over the given period, in order to obtain a first corrected curve. This ensures that the first corrected curve does not include consumption due to heating, especially for the first activation of the hot water tank during periods of off-peak hours. This correction can be applied to midday periods of off-peak hours and to nighttime periods of off-peak hours.

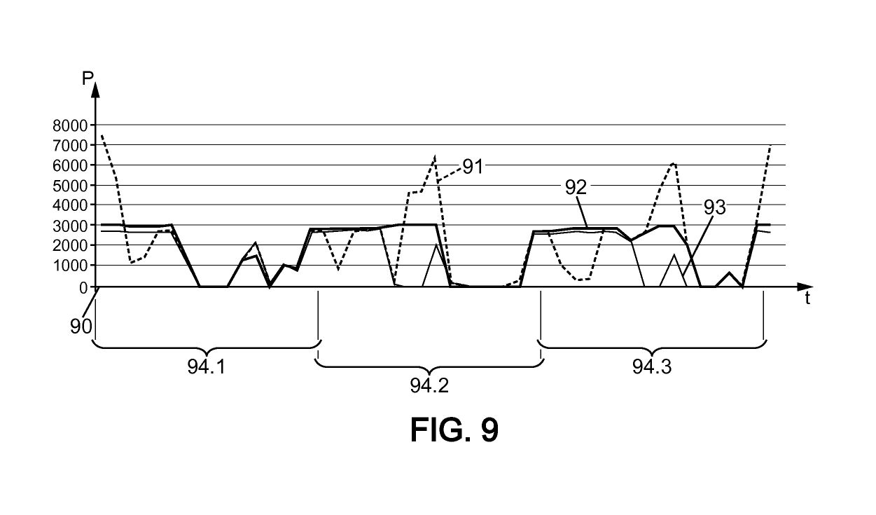

The application of the first correction is illustrated in FIG. 9. FIG. 9 is a diagram 90 showing the estimation 91 of the electric energy consumption of the hot water tank provided by the second estimation unit 15, uncorrected, over a given period of three days in which only the respective periods of off-peak hours 94.1, 94.2, and 94.3 are shown. Diagram 90 also shows the first corrected curve, labeled 92, in which the power has been limited to the value of Pmax. For comparison, diagram 90 also shows the actual consumption 93 of the hot water tank over the given period.

In the rest of the description, the first corrected curve is denoted ECS₁(t). However, as the first correction is optional, ECS₁(t) may also indicate the estimation 91 of the electric energy consumption of the hot water tank received from the second estimation unit 15.

The estimation device 11 further comprises a fourth estimation unit 19, adapted to apply a second correction to curve ECS₁(t) in order to obtain a second corrected curve ECS₂(t).

During a period of off-peak hours, the hot water tank is activated during a first activation period, which usually lasts more than an hour and a half. As mentioned above, the lower envelope determined by determination unit 14 may be built on the sliding minima with n equal to 3. In order to determine the lower envelope at a given moment, it is thus necessary to take into account the load curve an hour and a half before the given moment, and one and a half hours after the given moment (still assuming regular intervals of 30 minutes).

Thus, one and a half hours after a period of off-peak hours begins, the lower envelope substantially coincides with the load curve, and the estimation of the electric energy consumption of the hot water tank, obtained by the difference between the curve load and the lower envelope, is close to zero. The estimate is therefore skewed.

The same problem arises when n is 1 or 2.

The second correction thus consists of extending the first activation period for curve ECS₁(t) until the rate of change of the load curve reaches a sufficiently negative value (for example −40%).

The rate of change of the load curve, denoted ΔP(t), is determined as follows:

ΔP(t)=[P(t)−P(t−1)/P(t−1);

where P(t) represents the power consumed by the set of devices at given moment t and P(t−1) represents the power consumed by the set of devices at moment t−1 directly preceding given moment t.

In addition, t₀ denotes the starting moment of a period of off-peak hours and a variable ECS_plateau is initialized to the value of curve ECS₁ at moment t₀.

The second corrected curve is denoted ECS₂ and is obtained as follows, for all moments t following moment t₀ of the period of off-peak hours:

```
if t < t₀ + th₁ and if |ΔP(t)| < th₂, then ECS₂(t) = Max(ECS_plateau*
(1 + ΔP(t); ECS₁(t))
else
  if t ≧ t₀ + th₁ and |ΔP(t)| < th₃, then ECS₂(t) = ECS₁(t) and
  ECS_plateau = ECS₁(t);
  else
    if ΔP(t) < −th₄ or ΔP(t) > th₂ then ECS₂(t) = ECS₁(t) and
    ECS_plateau is set to the value of ECS₁(t) for the moments
    subsequent to moment t in the period of off-peak hours;
    else ECS₂(t) = ECS₁(t);
```

In the above formulas, Max(A,B) denotes the maximum value among A and B. In the algorithms presented in this patent application, the notation C=D indicates that the value of D is assigned to C.

th₁ is a predetermined threshold, expressed in hours, and may be set at 4 hours for example, in the context of a regular interval equal to 30 minutes.

th₂, th₃ and th₄ are also predetermined thresholds for the rate of change, expressed in percentages, and th₃ is less than th₂.

For example, within a context of a regular time interval of 30 minutes, thₑ can be equal to 15%, th₃ can be equal to 5%, and th₄, as previously mentioned, can be equal to 40%.

In this manner, the second corrected curve ECS₂(t) is obtained after the second correction.

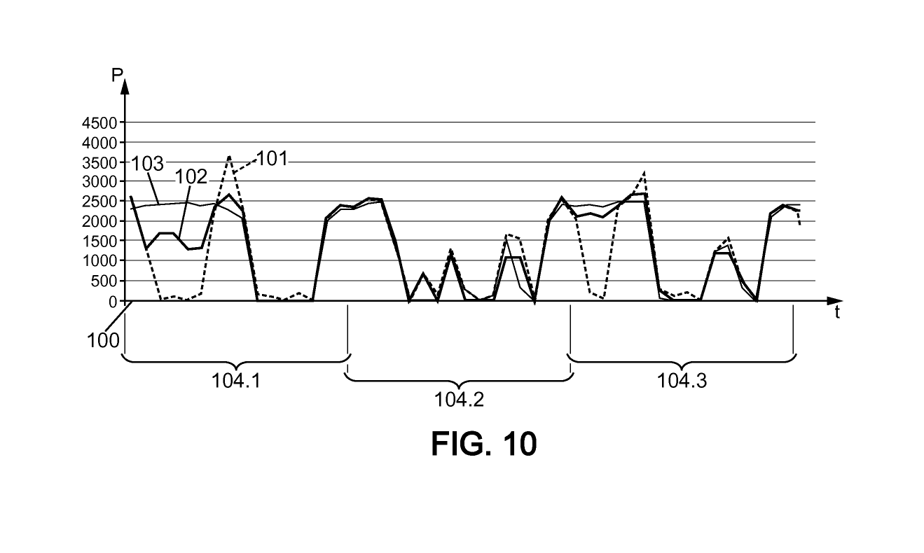

FIG. 10 is a diagram 100 showing the estimation 101 of the electric energy consumption of the hot water tank without any correction, over a given period of several days, with only the periods of off-peak hours 104.1, 104.2, and 104.3 being represented.

The estimation 101 has valleys reaching zero power consumption, about an hour and a half after the start of the first period of off-peak hours 104.1 and an hour and a half after the start of the third period of off-peak hours 104.3.

Diagram 100 also shows the second corrected curve ECS₂(t), labeled 102, where the valleys of the estimation 101 have been corrected to approach the actual consumption 103 of the hot water tank.

The fourth estimation unit 19 may apply a third correction to the second corrected curve ECS₂, to obtain a third corrected curve denoted ECS₃.

In FIG. 10, the second corrected curve still shows valleys (especially during the first period of off-peak hours 104.1) that do not correspond to actual consumption 103.

The invention may therefore provide a linear interpolation for the values of consumed electric energy in the second corrected curve ECS₂ that are less than one-third of the maximum power Pmax of the hot water tank and which are surrounded by high electric energy consumption by the hot water tank in the second corrected curve ECS₂, if they lie within the initial hours th₁ of a period of off-peak hours (particularly nighttime off-peak hours).

The second corrected curve can thus be obtained in the following manner, for all moments t following the moment prior to moment t₀+th₁:

$$if {ECS}_{2} ( t ) < \frac{P max}{3} , if {ECS}_{2} ( t - 1 ) > \frac{2 * P max}{3} , and if {ECS}_{2} ( t + 1 ) > \frac{2 * P max}{3}$$

$$then {ECS}_{3} ( t ) = \frac{{ECS}_{2} ( t - 1 ) + {ECS}_{2} ( t + 1 )}{2} ;$$

$$else {ECS}_{3} ( t ) = {ECS}_{2} ( t ) .$$

Again, we can consider a threshold th₁ that is equal to 4 hours.

In addition, the fourth estimation unit 19 may limit the third corrected curve ECS₃ at the end of the period of off-peak hours.

Indeed, at the end of a midday or nighttime period of off-peak hours, one can hypothesize that there is no increase in the power consumed by the hot water tank during the last 30 minute interval.

Denoting as t_{f} the end moment of an off-peak time window (for example, for a nighttime off-peak time window, we can consider t_{f}=t₀+8 hours); and as t_{f}−1 the moment immediately preceding moment t_{f} (which is 30 minutes before t_{f} in the example), the third curve can then be corrected as follows:

If ECS₃(t_{f})>ECS₃(t_{f}−1) then ECS₃(t_{f})=ECS₃(t_{f}−1).

The estimation device 11 further comprises a fifth estimation unit 20 adapted to apply a fourth correction to the third corrected curve ECS₃(t) in order to obtain a fourth corrected curve ECS₄(t). As the previously applied third correction is optional, the fourth correction may be applied to the second corrected curve ECS₂(t), or even to the estimation ECS₁(t). In the following, the fourth correction is applied to the third corrected curve ECS₃(t) for illustrative purposes only.

One will recall that the hot water tank operates during activation periods contained within a period of off-peak hours of the given period. During nighttime periods of off-peak hours, there is often a second activation when the temperature of the water in the hot water tank falls below a predetermined threshold for example.

The fourth correction is therefore applicable in a period of off-peak hours comprising at least a first activation period and a second activation period.

Usually, the hot water tank is activated early in a period of off-peak hours, then stops once a set temperature is reached. Heat loss during the night mechanically results in a lower water temperature in the tank. The hot water tank is activated a second time at the end of a nighttime period of off-peak hours, usually for a second activation period that is shorter than the first activation period, to heat the water to the desired temperature. Such a phenomenon can occur, for example, when a household member gets up and showers very early.

In addition, in practice the estimation of the first activation is more accurate than that of the second activation. The power drawn early in the period of off-peak hours is easier to detect because it is synchronized with a rate signal indicating the change to off-peak rates, with no other usages adding noise to the load curve.

To improve the estimation of the second activation, the invention may use distributions of ratios between the maximum power reached during the second activation and the maximum power reached during the first activation, in order to select a quantile of this ratio to define boundaries for the second activation estimation.

The fourth correction aims to improve the estimation concerning the second activation of the hot water tank.

A peak detection algorithm can be used to distinguish the first activation periods from subsequent activation periods and can be used to determine the maximum power value during the first activation period.

Then, as long as the electric energy consumption is greater than a certain fraction of the maximum power of the first activation (for example more than half of the maximum power of the first activation), the first activation period can still be considered to be in progress.

Once the power drops below said fraction, subsequent power draws are considered to be reactivations that are therefore part of the second activation period.

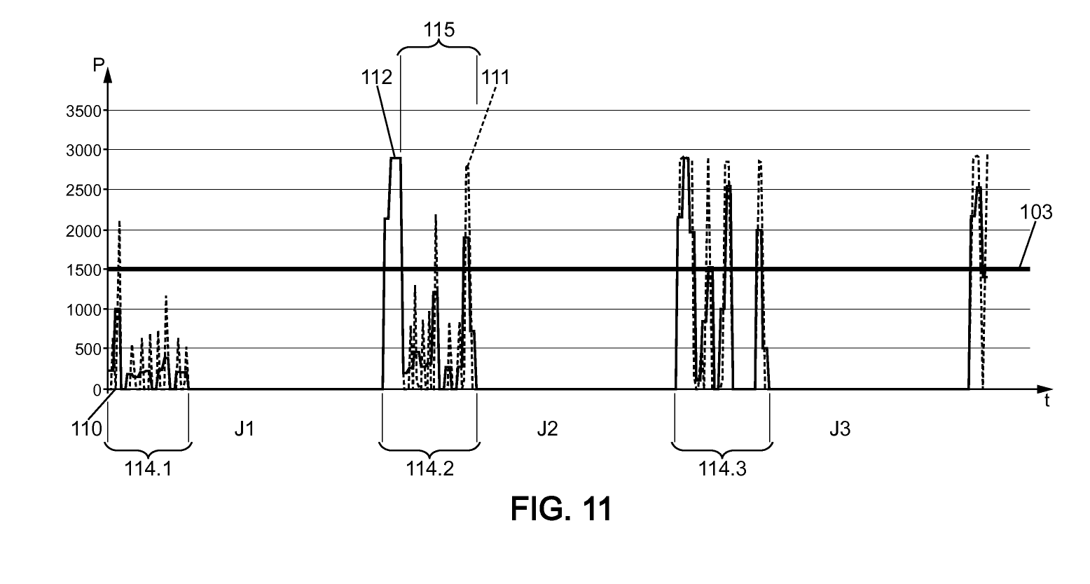

To illustrate this, FIG. 11 is a diagram 110 showing, over three consecutive days containing three periods of off-peak hours 114.1, 114.2, and 114.3, the evolution in the actual consumption of the hot water tank, at regular intervals of 10 minutes (curve 111) and 30 minutes (curve 112). The actual consumption curves (not estimates or corrected estimates) are used to determine the value for the fraction (half for example) of the maximum power of the first activation. In the example shown, the chosen value is equal to 1500 W. The second period of off-peak hours 114.2 therefore has a second activation period labeled 115, which begins when curve 112 or 111, after having first exceeded the 1500 W value, falls back below this value.

The starting moment of the second activation period 115 is denoted t₁. This moment is the moment of demarcation between the first activation period and the second activation period, for a period of off-peak hours.

Thus, once moment t₁ has been determined, it is possible to determine from the actual consumption curves 111 and 112, the maximum power achieved during activation.

To do so, a median value of the ratio of the actual maximum powers among the first and second activations can be determined according to:
the type of customer (nighttime (1 time window), midday (two time windows), midday (three time windows)). Indeed, off-peak hours usually consists of eight hours a day during which a customer has a reduced rate for his consumption of electric energy. These eight hours may be consecutive and at night for nighttime customers (usually from 10 pm to 6 am). Alternately, the eight hours may be broken up into two or three time windows (one or two of them occurring during the midday period). In this case, six off-peak hours may be provided during the night and two off-peak hours may be provided between 12 noon and 5 pm (midday off-peak hours);
the total volume of the hot water tank (200 L or less, from 201 L to 300 L, or more than 300 L);
the season and the type of day. The type of day is the day when a nighttime period of off-peak hours begins. For example, for a period of off-peak hours extending from 10 pm Monday to 1 am Tuesday, the type of day is Monday.

The fourth correction thus consists of setting boundaries for the second activation in the third corrected curve ECS₃(t), at the maximum value of the third corrected curve ECS₃(t) during the first activation period, weighted by the median of the group to which the household belongs. The median thus constitutes a threshold denoted th_{second} below.

The fourth corrected curve ECS₄ is therefore obtained as follows:

$$for t ∈ [ {t}_{0} ; {t}_{1} ] , {ECS}_{4} ( t ) = {ECS}_{3} ( t ) ; \\ for t ∈ ] {t}_{1} ; {t}_{f} ] , {ECS}_{4} ( t ) = Min \{ {Max}_{t < {t}_{1}} \{ {ECS}_{3} ( t ) \} \times {th}_{second} ; {ECS}_{3} ( t ) \} ,$$

Min(A;B) indicating the minimum among A and B.

ECS₃(t) can be replaced in the above algorithm by either ECS₂(t) or ECS₁(t), depending on the corrections made to the estimation provided by the second estimation unit 15.

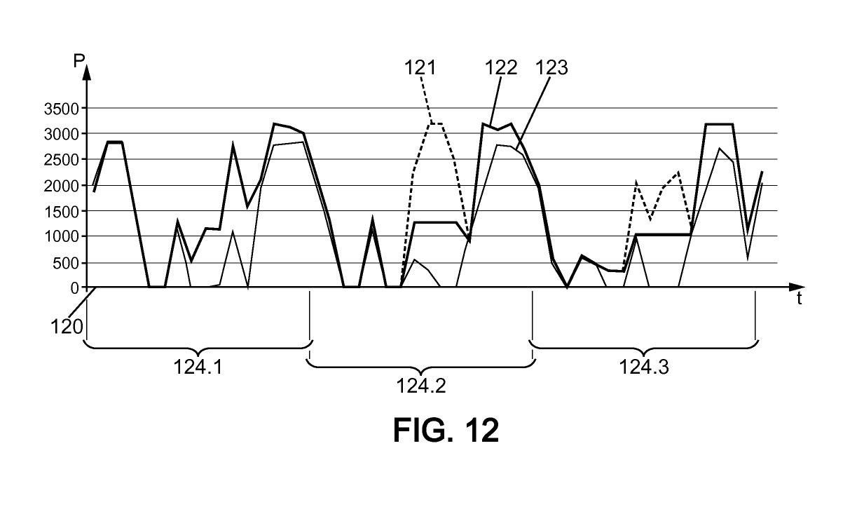

To illustrate the contribution of the fourth correction, FIG. 12 is a diagram 120 showing the estimation 121 of the electric energy consumption of the hot water tank without any correction, over a period of several days, with only the periods of off-peak hours 124.1, 124.2, and 124.3 represented. One will note that during the second period of off-peak hours 124.2, a power peak exceeding 3000 W is reached by curve 121 during a second activation period, which is far from the actual consumption curve of the hot water tank, denoted 123.

The fourth corrected curve ECS₄(t) is denoted 122, and a plateau can be observed during the second activation period in the second period of off-peak hours 124.2, in place of the power peak in the estimation 121.

The estimation of the electric energy consumption curve for the hot water tank is therefore considerably improved by applying the fourth correction.

The electric energy consumption curve of the hot water tank estimated in this manner, and possibly corrected, can help predict the operation of the hot water tank during periods of off-peak hours. For this purpose, the estimated and possibly corrected electric energy consumption curve is sent to a prediction unit 22 by a transmission unit 21 of the estimation device 11. It is thus possible to construct a model predicting the length of operation of the hot water tank per period of off-peak hours.

To do so, an alternative to the linear regression method can be used: quantile regression.

Quantile regression predicts a quantile (for example the median) of a variable of interest, rather than the mean.

Advantageously, and given that the estimation method described above overestimates the lengths of operation of the hot water tank, a quantile regression using 40% corrects this bias, combining the estimation error and the error of the prediction model to provide an error centered at zero.

Variables are selected for the quantile regression. These may be variables significant at a certain level of probability for the quantile used. For example, the most regular variables observed for the greatest number of customers are, in this order:
for nighttime customers: general consumption of the day before, season, length of use of the hot water tank the day before and two days before, type of day (days when off-peak hours begin), length of use of the hot water tank on D-3, general consumption two days ago, then all lengths of use of the hot water tank back to D-7 and the length of use of the hot water tank on D-14;
for the nighttime period of off-peak hours of midday customers: length of use of the hot water tank, general consumption of the day before, season, length of use of the hot water tank during the nighttime period of off-peak hours two days ago, days where off-peak hours begin (Sunday evening and Tuesday evening);
for the midday period of off-peak hours of midday customers: season, days when weekend off-peak hours begin (Thursday evening to Sunday evening), length of use of the hot water tank in the nighttime period of off-peak hours the day before, general consumption of the day before.

Predicting the length of operation of the hot water tank is heavily dependent on the season. The starting time of the learning period may vary depending on the month in which the prediction is made. For example, in order to predict the lengths of operation for the months of January to April, historical load curves beginning in October may be used.

In addition, the quantile provided for the regression can depend on the customer and on the month. This dependency is illustrated in Table 1 below:

TABLE 1
Quantile determination according to type of customer and
according to the month to be predicted.

| | | | Midday | |
|---|---|---|---|---|
| | | Nighttime | customers | |
| | | customers | Night- | |
| | Start of learning | Nighttime | time | Midday |
| Month | period | period | period | period |
| January | October | 0.35 | 0.50 | 0.50 |
| February | October | 0.40 | 0.40 | 0.50 |
| March | October | 0.45 | 0.50 | 0.50 |
| April | October | 0.50 | 0.50 | 0.50 |
| May | February | 0.50 | 0.50 | 0.60 |
| June | March | 0.50 | 0.50 | 0.50 |
| July | April | 0.50 | 0.50 | 0.50 |
| August | May | 0.50 | 0.50 | 0.50 |
| September | May | 0.50 | 0.50 | 0.50 |
| October | May | 0.50 | 0.50 | 0.50 |
| November | July | 0.40 | 0.50 | 0.50 |
| December | September | 0.30 | 0.40 | 0.50 |

For example, for a nighttime customer and a January estimation, the learning period begins in October and 35% is used for the quantile regression.

Once the input variables are selected and the quantiles to be estimated are determined, the parameters are estimated using an optimization algorithm rather than the usual least squares method such as linear regression. Such optimization algorithms are well known to those skilled in the art.

A simpler prediction model consists of considering the length of operation on day D+1 to be equal to the length of operation on day D.

From the estimation, possibly corrected, of the electric energy consumption of a given device among a set of devices, the following applications can be provided and implemented by an application unit 23:
with production of solar (photovoltaic) energy, moving the operating hours of the hot water tank to the hours of full sun;
optimizing the general load curve by moving the electric energy consumption of the hot water tank to the end of the nighttime period of off-peak hours, where supply costs are lower;
providing a detailed bill to end customers, with itemized usage, and with advice and diagnostics on use of the hot water tank.

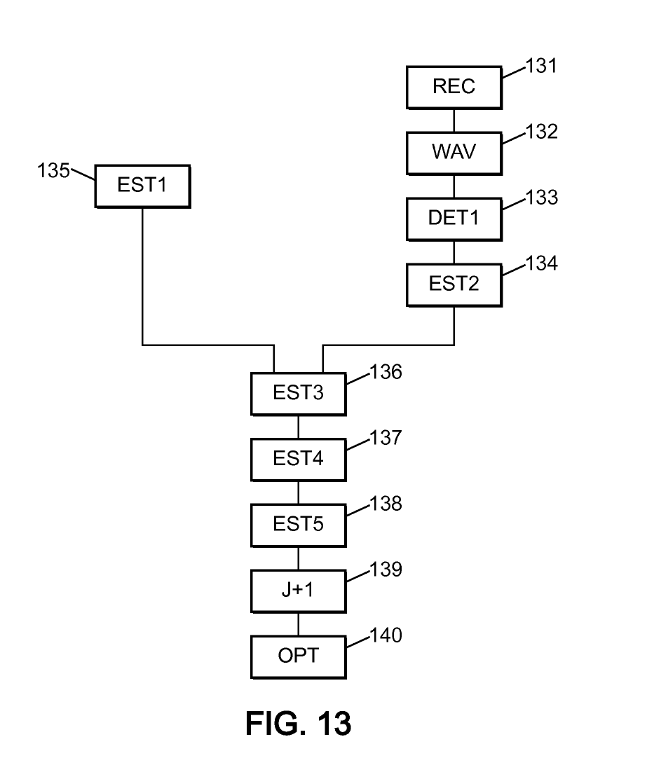

FIG. 13 is a diagram illustrating the steps of a method according to an embodiment of the invention.

In step 131, the load curve is received by the receiving unit 12.

In step 132, an optional step of denoising the load curve can be applied by the denoising unit 13, as detailed above.

In step 133, a lower envelope of the load curve is determined by the determination unit 14, as described in the above discussion.

In step 134, an electric energy consumption curve for the given electrical device over the given period is estimated by subtracting the determined lower envelope from the load curve. As explained above, step 134 may be implemented by the second estimation unit 15.

In step 135, the maximum power Pmax consumed by the given device is estimated by the first estimation unit 16, using one of the two methods described above.

In optional step 136, a first correction is applied to the electric energy consumption curve estimated in step 134, by the third estimation unit 18, based on the maximum power Pmax estimated in step 135. A first corrected curve is obtained.

In optional step 137, a second and/or third correction is applied to curve ECS₁(t) (first corrected curve or estimated uncorrected curve), by the fourth estimation unit 19, to obtain a second corrected curve ECS₂(t) or a third corrected curve ECS₃(t).

In optional step 138, a fourth correction may be applied to curve ECS₁(t), to the second corrected curve ECS₂(t), or to the third corrected curve ECS₃(t), by the fifth estimation unit 20, to obtain a fourth corrected curve ECS₄(t), as described above.

In optional step 139, a prediction of the length of operation of the given electrical device may be obtained by the prediction unit 22, based on one of the curves ECS₁(t), ECS₂(t), ECS₃(t), and ECS₄(t).

In optional step 140, one of the applications of the invention described above may be implemented by the application unit 23.

1. A method for estimating the electric energy consumption of a given electrical device among a set of electrical devices, comprising the steps of:
receiving a load curve representative of the electric energy consumption of said set of electrical devices at given moments, over a given period;
determining a lower envelope of said load curve;
estimating an electric energy consumption curve for the given electrical device over the given period, by subtracting the determined lower envelope from said load curve.

2. The method according to claim 1, wherein the given moments are spaced apart at regular intervals, said regular intervals being greater than one minute.

3. The method according to claim 1, wherein the given electrical device is a hot water tank and wherein the given period comprises at least one period of off-peak hours, and wherein the estimation of the electric energy consumption curve of the electrical device is restricted to said at least one period of off-peak hours.

4. The method according to claim 1, further comprising a step of estimating the maximum power consumed by said given device, and a step of applying a first correction to said estimated curve in order to obtain a first corrected curve, said first correction consisting of limiting the power consumed by said electrical device to values less than said maximum power, over the given period.

5. The method according to claim 3, wherein the volume of the hot water tank is known, and wherein the maximum power consumed is estimated from said volume.

6. The method according to claim 4, wherein the volume of the hot water tank is known, and wherein the maximum power consumed is estimated from said volume.

7. The method according to claim 4, wherein a continuous load curve representing the electric energy consumption of the set of devices for a period prior to said given period is stored, said prior period being continuous and comprising at least some periods of off-peak hours and periods of peak hours, and wherein the step of estimating the maximum power consumed by said electrical device comprises:
determining, for each prior period of off-peak hours, the difference between the value of the load curve at moment one or at moment two in said period of off-peak hours and the value of the load curve at the moment immediately preceding said moment one;
estimating, from the determined differences, the maximum power consumed by said electrical device.

8. The method according to claim 1, wherein, upon receipt of the load curve, the method comprises the application of a wavelet decomposition in order to obtain a denoised load curve, and wherein the lower envelope is determined from the denoised load curve, and the electric energy consumption curve of the given device is estimated by subtracting the lower envelope from the denoised load curve, over the given period.

9. The method according to claim 1, wherein the load curve is also received for periods before and after the given period, and wherein the step of determining the lower envelope of the load curve comprises the following steps, for each moment in the given period:
determining the minimum value among the respective values of the load curve for the n moments before the given moment, for the given moment, and for the n moments after the given moment, where n is integer greater than or equal to one;
assigning the determined minimum value to said moment,
said minimum values being connected to obtain the lower envelope of the load curve.

10. The method according to claim 9, wherein a rate of change T[P(t)] of the load curve at a given moment t of the given period is determined as follows:
T[P(t)]=[P(t)−P(t−1)/P(t−1)
where P(t) represents the power consumed by the set of devices at given moment t and where P(t−1) represents the power consumed by the set of devices at moment t−1 directly preceding given moment t;
said method further comprising a step of applying a second correction to said estimated curve denoted ECS₁, in order to obtain a second corrected curve denoted ECS₂,
where t₀ is the starting moment of a period of off-peak hours of the given period, a variable ECS_plateau being initialized to the value of the estimated curve ECS₁ at moment t₀,
said second corrected curve being obtained in the following manner, for all moments t following moment t₀ of said period of off-peak hours:
```
if t < t₀ + th₁ and if |T[P(t)]| < th₂, then ECS₂(t) = Max(ECS_plateau*
(1 + T[P(t)]; ECS₁(t))
else
  if t ≧ t₀ + th₁ and |T[P(t)]| < th₃, then ECS₂(t) = ECS₁(t) and
  ECS_plateau = ECS₁(t);
  else
    if T[P(t)] < −th₄ or T[P(t)] > th₂ then ECS₂(t) = ECS₁(t) and
    ECS_plateau is set to the value of ECS₁(t) for the moments
    subsequent to moment t in the period of off-peak hours;
    else ECS₂(t) = ECS₁(t);
```
where Max(A,B) indicates the maximum value among A and B;
where th₁ is a predetermined threshold expressed in hours,
where th₂, th₃, and th₄ are predetermined thresholds expressed in percentages, th₃ being less than th₂.

11. The method according to claim 4, wherein the maximum power consumed by said given device is denoted Pmax, wherein the method further comprises a step of applying a third correction to the second corrected curve ECS₂, in order to obtain a third corrected curve denoted ECS₃,
said third corrected curve being obtained as follows, for all moments t preceding moment t₀+th₁:
$$if {ECS}_{2} ( t ) < \frac{P max}{3} , if {ECS}_{2} ( t - 1 ) > \frac{2 * P max}{3} , and if {ECS}_{2} ( t + 1 ) > \frac{2 * P max}{3}$$
$$then {ECS}_{3} ( t ) = \frac{{ECS}_{2} ( t - 1 ) + {ECS}_{2} ( t + 1 )}{2} ;$$
$$else {ECS}_{3} ( t ) = {ECS}_{2} ( t ) .$$

12. The method according to claim 11, wherein the maximum power consumed by said given device is denoted Pmax, wherein the method further comprises a step of applying a third correction to the second corrected curve ECS₂, in order to obtain a third corrected curve denoted ECS₃,
said third corrected curve being obtained as follows, for all moments t preceding moment t₀+th₁:
$$if {ECS}_{2} ( t ) < \frac{P max}{3} , if {ECS}_{2} ( t - 1 ) > \frac{2 * P max}{3} , and if {ECS}_{2} ( t + 1 ) > \frac{2 * P max}{3}$$
$$then {ECS}_{3} ( t ) = \frac{{ECS}_{2} ( t - 1 ) + {ECS}_{2} ( t + 1 )}{2} ;$$
$$else {ECS}_{3} ( t ) = {ECS}_{2} ( t ) .$$

13. The method according to claim 11, wherein said given device operates in activation periods contained within a period of off-peak hours of the given period, wherein electric power is consumed by the given electrical device only during the activation periods, the period of off-peak hours comprising at least a first activation period and a second activation period,
wherein the method further comprises the application of a fourth correction to the second corrected curve ECS₂ in order to obtain a fourth corrected curve denoted ECS₄, said fourth correction comprising:
determining a moment t₁ of demarcation between the first activation period and the second activation period;
determining a second activation threshold th_{second}, expressed in percentages; and the fourth corrected curve ECS₄ being obtained as follows:
$$for t ∈ [ {t}_{0} ; {t}_{1} ] , {ECS}_{4} ( t ) = {ECS}_{2} ( t ) ; \\ for t ∈ ] {t}_{1} ; {t}_{f} ] , {ECS}_{4} ( t ) = Min \{ {Max}_{t < {t}_{1}} \{ {ECS}_{2} ( t ) \} \times {th}_{second} ; {ECS}_{2} ( t ) \}$$
where Min(A;B) indicates the minimum among A and B;
t_{f} being an ending moment of the given period.

14. The method according to claim 11, wherein the fourth correction is applied to the third corrected curve ECS₃.

15. The method according to claim 12, wherein the fourth correction is applied to the third corrected curve ECS₃.

16. The method according to claim 1, further comprising the prediction of the length of operation of the given electrical device for a period subsequent to the given period, based on the electric energy consumption curve of the electrical device over the given period.

17. A non-transitory computer readable storage medium, with a program stored thereon, wherein the program comprises program instruction code for executing the steps of the method according to claim 1.

18. A device for estimating the electric energy consumption of a given electrical device among a set of electrical devices, comprising the following units:
a unit for receiving a load curve representative of the electric energy consumption of said set of electrical devices at given moments, over a given period;
a unit for determining a lower envelope of said load curve;
a unit for estimating an electric energy consumption curve of the electrical device over the given period, by subtracting the determined lower envelope from said load curve.
